(19) United States
(12) Patent Application Publication
(10) Pub. No.: US 2017/0369998 A1
(43) Pub. Date: Dec. 28, 2017

(54) NANOFIBER-COATED FIBER AND METHODS OF MAKING

(71) Applicant: FREE FORM FIBERS, LLC, Saratoga Springs, NY (US)

(72) Inventors: Joseph PEGNA, Saratoga Springs, NY (US); Erik G. VAALER, Redwood City, CA (US); John L. SCHNEITER, Cohoes, NY (US); Shay L. HARRISON, East Schodack, NY (US); Ram K. GODUGUCHINTA, Ballston Lake, NY (US); Kirk L. WILLIAMS, Saratoga Springs, NY (US)

(73) Assignee: FREE FORM FIBERS, LLC, Saratoga Springs, NY (US)

(21) Appl. No.: 15/631,243

(22) Filed: Jun. 23, 2017

Related U.S. Application Data
(60) Provisional application No. 62/353,667, filed on Jun. 23, 2016.

(51) Int. Cl. C23C 16/48; B82Y 40/00; B82Y 30/00; B32B 5/14; B32B 5/04; C23C 16/56; B29C 70/06

(52) U.S. Cl. CPC C23C 16/483; C23C 16/56; B82Y 40/00; B29C 70/06; B32B 5/14; B32B 5/04; B82Y 30/00

(57) ABSTRACT

Methods are provided for making a nanofiber-coated fiber. The method(s) include: providing a base fiber; depositing a nanofreckle on the base fiber; and growing a nanofiber at the nanofreckle. In another aspect, nanofiber-coated fibers are provided, produced by the above-noted methods making a nanofiber-coated fiber.

### CROSS-REFERENCE TO RELATED APPLICATION

This application claims the benefit of U.S. provisional patent application Ser. No. 62/353,667, filed Jun. 23, 2016, entitled “Nanofiber-Coated Fiber and Methods of Making”, which is hereby incorporated herein by reference in its entirety.

### STATEMENT REGARDING GOVERNMENT RIGHTS

Certain aspects of this invention were made with United States Government support under a US Department of Energy Award DE-SC0011954, as well as Contract Award ID No. IIP-1152698, awarded by the National Science Foundation (NSF). Accordingly, the U.S. Government may have certain rights in this invention.

### BACKGROUND

The present invention relates generally to the field of fibers for reinforcing materials.

In a wide variety of applications, fiber composite materials, incorporating fibers into a surrounding material matrix, provide higher performance than traditional, non-fiber materials. In many cases, however, the full promise of the fiber composite material is not realized owing to poor coupling between the fibers and the surrounding material matrix.

### SUMMARY

Opportunities exist to improve fiber-to-matrix coupling through the use of a nanofiber coating applied to the fiber.

The opportunities are addressed, in one or more aspects of the present invention, by providing a method of making a nanofiber-coated fiber, the method comprising: providing a base fiber; depositing a nanofreckle (nanoparticle catalyst) on the base fiber; and growing a nanofiber at the nanofreckle.

In one or more other aspects of the present invention, an article of manufacture is provided comprising a nanofiber-coated fiber made by the aforesaid method of making a nanofiber-coated fiber.

Additional features and advantages are realized through the techniques of the present invention. Other embodiments and aspects of the invention are described in detail herein and are considered a part of the claimed invention.

### DRAWINGS

These and other features, aspects, and advantages of the present invention will become better understood when the following detailed description is read with reference to the accompanying drawings in which like characters represent like parts throughout and, wherein:

FIG. 1 is a schematic representation of a single-fiber reactor, showing a seed fiber substrate, a reactor cube into which precursor gases are delivered, a focused laser beam impinging on the seed fiber, and reactor windows that are transparent to the incoming laser beam wavelength and allow for video monitoring of the process, in accordance with one or more aspects of the present invention;

FIG. 2 is a schematic view showing how fiber LCVD can be massively parallelized by multiplication of the laser beams, in accordance with one or more aspects of the present invention;

FIG. 3 is an example of parallel LCVD growth of carbon fibers, in accordance with one or more aspects of the present invention;

FIG. 4 depicts one embodiment of a plurality of rebarred fibers (that is, fibers with a varying or non-uniform diameter) that may be formed by Digital Spinneret (DS) technology, in accordance with one or more aspects of the present invention;

FIG. 5 depicts one embodiment of an apparatus for facilitating fabricating a plurality of fibers having multiple discrete coating regions, in accordance with one or more aspects of the present invention;

FIG. 6 depicts one embodiment of a nanoporous carbon layer, in accordance with one or more aspects of the present invention; and

FIG. 7 illustrates one embodiment of a nanofiber-coated fiber, in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, fabrication and processing techniques, etc., are omitted so as to not unnecessarily obscure the invention in detail. It should be understood, however, that the detailed description and the specific example(s), while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure. Note further that numerous inventive aspects and features are disclosed herein, and unless inconsistent, each disclosed aspect or feature is combinable with any other disclosed aspect or feature as desired for a particular application, for instance, for facilitating providing nanofiber-coated fibers and methods of making, as described herein.

Disclosed herein, in one or more aspects, are are high specific strength fibers that are neither graphitic carbon, nor Carbon Nanotube (CNT)-based, nor graphene. At a density of 2.34 g/cc (29% heavier than Carbon fiber (Cf)) the tensile strength of amorphous Boron fiber (aBf) was measured at 12-17 GPa (72-144% over the highest strength Cf—Hexcel IM-10). Awareness of boron's exceptional specific strength is not new. In fact, nearly 60 years ago now, it led to a massive NASA-driven effort to develop boron fibers. It took 25 years for this effort to bear fruit, with the development in the 1970's of the tungsten-cored boron monofilament now commercialized by SMI. This long history bears witness to design aspirations unrequited by process development. Those aspirations may finally have met their match in the DS process disclosed herein. But meeting the goal of high specific strength, small diameter and pure aBf may also bring to the fore new issues that we seek to address.

In composite materials, especially those with low modulus matrix like polymers, load is carried in tension by the fibers and transmitted fiber-to-fiber in shear by the matrix. As density and specific strength increase, the volume of fibers that is needed at equivalent load goes down. So does in fact the amount of matrix, thus amplifying weight reduction. But the surface area available for shear load transfer decreases too. For example, in the extreme case where aB_{f} diameter is 10 times that of C_{f} and specific strength 4 times as much, the specific surface area available for shear load transfer is decreased by a factor of 50. This may not be enough of a decrease to be cause for concern. If it ever was, however, the present innovation offers two complementary features. The first increases matrix toughness and fiber adhesion with “furry aB_{f}” that are coated with Nanotubes (NT). The second increases composite toughness and fatigue life with “rebars” built into the fiber as diameter variations.

One or more aspects of the present invention build upon earlier innovations with the invention of the Digital Spinneret (DS), such as described in commonly assigned, U.S. Patent Publication No. 2015/0004393 A1, entitled “High Strength Ceramic Fibers and Methods of Fabrication”, which is hereby incorporated herein by reference in its entirety. The DS is the first ever process to produce parallel fibers by ‘laser-printing.’ Fibers are produced in the form of a ‘ribbon’ that can be collected onto a tape, such as described in commonly assigned, U.S. patent application Ser. No. 15/592,408, filed May 11, 2017, entitled “Fiber Delivery Assembly and Method of Making”, which is also incorporated herein by reference in its entirety . It should be noted that the ribbon packaging is another “first” for fibers. In fact, one can show mathematically that fiber volume fraction can arbitrarily approach the theoretical limit of (˜78%), whereas tows seldom achieve over 40%. Such high density packing further decreases the need for quantity of matrix, hence reducing weight and increasing composite specific strength some more, but also likely demanding a tougher matrix material. The DS is particularly well-suited for hard-to-process materials such as ceramics, refractory metals (e.g. tungsten) and metalloids (such as boron).

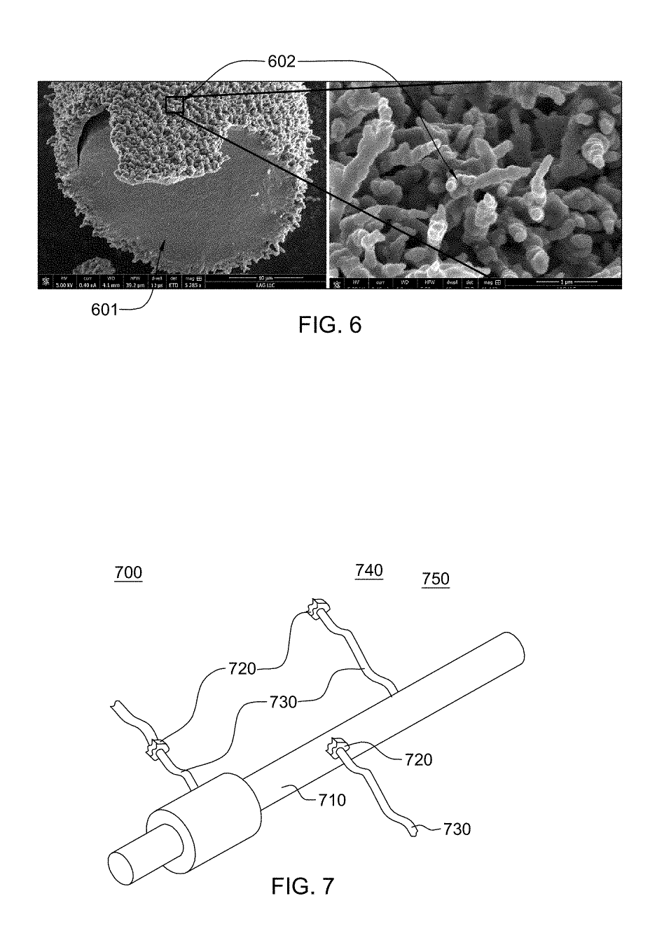

The other foundational proprietary technology that is brought to bear in this innovation is a unique LCVD fiber coating process. Currently, this is believed to be the only fiber coating technology that can be used to write patterns onto the fibers as the laser can be indexed to be turned on or off along the length of the fibers. An example of this unique capability, which we call “Spot Coating,” is shown in FIG. 6 discussed below. This approach can also be used for micro-embedding sensors and actuators into advanced functional fibers.

Laser Printed aB_{f}^{:}

As illustrated in experimental graphs in U.S. Pat. No. 5,399,430 to Paul C. Nordine, entitled “Boron Fibers Having Improved Tensile Strength” (hereinafter Nordine), the faster the fiber grows, the more it is amorphous and the better is its strength. Nordine and others used low pressure BCl₃ and H2 as a precursor mix and reported growth rates reaching into the mm/s range.

Diborane (B₂H₆) is also a viable precursor commonly used in microelectronics for boron doping, which can also be used for boron fibers; that is, as precursor on the assumption that its low activation energy would yield high growth rates.

NT-coated aB_{f};

This innovation uses spot coating for Laser Induced Catalytic CVD (LCCVD), where the catalyst is co-deposited by CVD. An example of co-deposited catalyst is ferrocene, which results in nanofreckles of iron that are in turn a catalyst for the growth of NT.

Rebars:

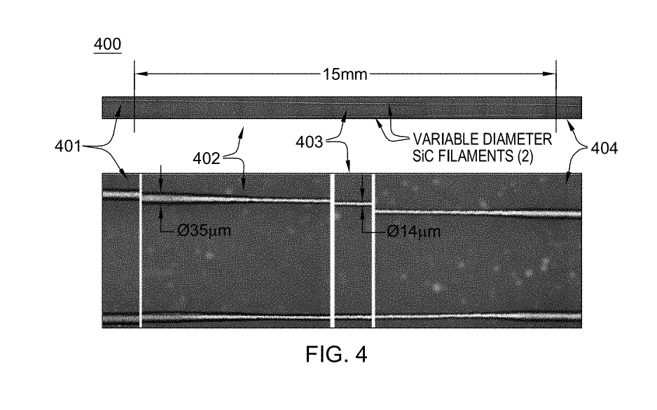

The ability to produce fibers with tightly controlled diameter profiles has been demonstrated by the lead-inventor and his colleagues. FIG. 4 herein illustrates the exquisite control the present approach confers to the fabrication of the first ever ribbons of periodically varying SiCf. Variable diameter fibers offer rebar features that enhance fracture toughness and increases fatigue life by an order of magnitude. In contrast, with uniform fiber diameter, smoother and longer cracks form in the matrix that are bridged by fibers until those snap and pull out.

Before describing the above-noted aspects further, note that the present invention incorporates or utilizes the following, alone or in any combination, and/or in combination with the subject matter of commonly assigned, PCT International Application No. PCT/US2015/037080, which published on Dec. 30, 2015, as PCT Patent Publication No. WO 2015/200257 A1, and with commonly assigned, U.S. patent application Ser. No. 15/320,800, entitled “An Additive Manufacturing Technology for the Fabrication and Characterization of Nuclear Reactor Fuel”, and with commonly assigned, U.S. patent application Ser. No. 15/592,408, filed May 11, 2017, entitled “Fiber Delivery Assembly and Method of Making”, each of which is hereby incorporated herein by reference in its entirety.

Fiber-reinforced composite materials are designed to concomitantly maximize strength and minimize weight. This is achieved by embedding high-strength low-density fibers into a low-density filler matrix in such a way that fibers channel and carry the structural stresses in composite structures. The matrix serves as a glue that holds fibers together and helps transfer loads in shear from fiber to fiber, but in fact the matrix material is not a structural element and carries but a negligible fraction of the overall structural load seen by a composite material.

Composites are thus engineered materials made up of a network of reinforcing fibers—sometimes woven, knitted or braided—held together by a matrix. Fibers are usually packaged as twisted multifilament yarns called “tows”. The matrix gives rise to three self-explanatory classes of composite materials: (1) Polymer Matrix Composites (PMCs), sometimes-called Organic Matrix Composites (OMCs); (2) Metal Matrix Composites (MMC's); and (3) Ceramic Matrix Composites (CMCs).

Such an approach to composite materials in which the tows are but a disorganized bundle of entangled filaments constrains the fibers to a purely structural role. A new approach to the fabrication of multilayered fibers called 1½-D printing allows for the formation of parallel, evenly spaced, parallel filaments. Together, this construct constitutes an arbitrary long ribbon of continuous filaments that allow the fiber to break out of their purely structural functions, and enable sweeping new designs in which the fibers contain embedded microsystems. This is described further in the above-referenced, commonly assigned, co-filed U.S. patent application Ser. No. 15/592,408.

This approach to fiber manufacturing has been proposed for example as a means to produce TRISO-inspired nuclear fuel embedded within fibers for subsequent embedding into a refractory matrix to form an accident tolerant CMC nuclear fuel, such as described in the above-referenced, commonly assigned PCT Patent Publication No. WO 2015/200257 A1. However, this is but one instance of possible new designs enabled by this technology.

At its core, 1½-D printing rests on the physical principles of Laser Induced Chemical Vapor Deposition to both print continuous filaments and deposit patterns coated onto the fiber. U.S. Patent Publication No. 2015/0004493 A1, Pegna et al., teaches how arrays of filaments can be laser-printed, with diameters potentially varying along their length. The above-referenced, PCT Patent Publication No. WO 2015/200257 A1 teaches how a laser incident to the ribbon can be used to write a pattern of coatings onto a substrate fiber by turning the laser on or off as the ribbon advances. It also teaches that coating thickness can be adjusted. Finally, the above-referenced, commonly assigned and co-filed U.S. patent application Ser. No. 15/592,408, teaches how such ribbons of parallel filaments can be collected as ribbons onto a tape to enhance fiber volume fraction in the composite.

To implement 1½-D printing, Laser Induced Chemical Vapor Deposition (LCVD) was chosen as the fundamental Additive Manufacturing (AM) tool for its near material independence—an extremely rare property for AM processes. Such a process is said to be “Material Agnostic”. LCVD is a technique derived from CVD, used intensively in the microelectronics fabrication industry (aka “Chip Fab”). CVD builds up electronics-grade high-purity solid deposits from a gas precursor. In its 75+ year history, Chip Fab has accumulated an impressive library of chemical precursors for a wide range of materials, numbering in the 10's of thousands, including fissile material precursors. The main difference between CVD and LCVD resides in dimensionality and mass throughput. CVD is intended for 2-D film growth whereas LCVD is ideally suited for one-dimensional filamentary structures. The dimensionality difference means that deposition mechanisms are greatly enhanced for LCVD vs. CVD, leading to deposited mass fluxes (kg/m2 s) that are 3 to 9 orders of magnitude greater. For example, diamond-like carbon filaments have been measured at linear growth rates upwards of 13 cm/s, which represents a 9 order of magnitude increase in mass flux compared to thin film CVD of the same material. Finally, compared to extant fuel manufacturing, LCVD is essentially containerless, which virtually eliminates opportunities for material contamination by container or tool.

The following fundamental properties formally defines “1½-D Printing” AM

Material-agnostic ability to grow filaments.

Ability to vary diameter along the length of the filament, as illustrated in FIG. 10 of Pegna et al. (PCT Publication No. WO 2015/200257 A1).

Material-agnostic ability to vary composition along the length of the filament, as was demonstrated by Maxwell et al.

Material-agnostic ability to coat specific sections of filaments with a desired material, morphology and thickness; as illustrated by the nanoporous and other spot coatings shown in FIG. 11 of the above-referenced Pegna et al., PCT publication.

Disclosed herein, in part, is the concept of avoiding the use of polymeric precursors altogether by using laser-assisted chemical vapor deposition (LCVD) as is described in U.S. Pat. No. 5,786,023 by Maxwell and Pegna, the entirety of which is hereby incorporated by reference herein. In this process pure precursor gases (such as silane and ethylene in the case of SiC fiber production) are introduced into a reactor within which a suitable substrate such as glassy carbon is positioned, and laser light is focused onto the substrate. The heat generated by the focused laser beam breaks down the precursor gases locally, and the atomic species deposit onto the substrate surface and build up locally to form a fiber. If either the laser or the substrate is pulled away from this growth zone at the growth rate a continuous fiber filament will be produced with the very high purity of the starting gases. With this technique there are virtually no unwanted impurities, and in particular no performance-robbing oxygen.

Very pure fibers can be produced using LCVD, such as silicon carbide, boron carbide, silicon nitride and others. The inventors have discovered that if a material has been deposited using CVD, there is a good chance that fiber can be produced using LCVD. Unlike with liquid polymeric precursors, however, where the chemistry can be very involved and complicated even for relatively ‘simple’ materials such as those mentioned above, LCVD can also be used quite directly to produce novel mixes of solid phases of different materials that either cannot be made or have not been attempted using polymeric precursor and spinneret technology. Examples include fibers composed of silicon, carbon and nitrogen contributed by the precursor gases such as silane, ethylene and ammonia, respectively, where the resulting “composite” fiber contains tightly integrated phases of silicon carbide, silicon nitride and silicon carbonitrides depending on the relative concentrations of precursor gases in the reactor. Such new and unique fibers can exhibit very useful properties such as high temperature resistance, high strength and good creep resistance at low relative cost.

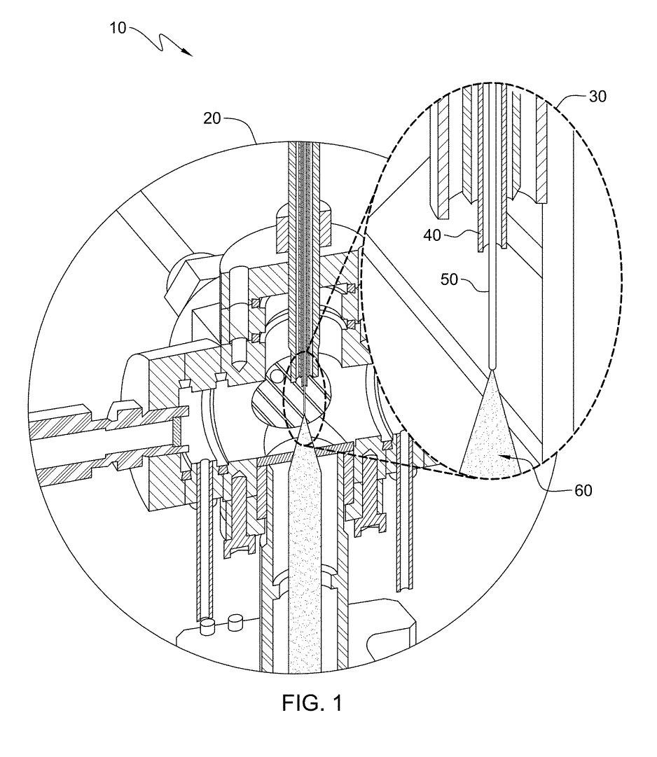

FIG. 1 shows a LCVD reactor into which a substrate seed fiber has been introduced, onto the tip of which a laser beam is focused. (It will be seen that the substrate may be any solid surface capable of being heated by the laser beam. It will further be seen that multiple lasers could be used simultaneously to produce multiple simultaneous fibers as is taught in International Patent Application Serial No. US2013/022053 by Pegna et al.,—also filed on Jul. 14, 2014 as U.S. patent application entitled “High Strength Ceramic Fibers and Methods of Fabrication”, U.S. Ser. No.14/372,085—the entireties of which are hereby incorporated by reference herein.) In accordance with that Application, FIG. 1 more particularly shows a reactor 10; enlarged cutout view of reactor chamber 20; enlarged view of growth region 30. A self-seeded fiber 50 grows towards an oncoming coaxial laser 60 and is extracted through an extrusion microtube 40.

A mixture of precursor gases can be introduced at a desired relative partial pressure ratio and total pressure. The laser is turned on, generating a hot spot on the substrate, causing local precursor breakdown and local CVD growth in the direction of the temperature gradient, typically along the axis of the laser beam. Material will deposit and a fiber will grow, and if the fiber is withdrawn at the growth rate, the hot spot will remain largely stationary and the process can continue indefinitely, resulting in an arbitrarily long CVD-produced fiber.

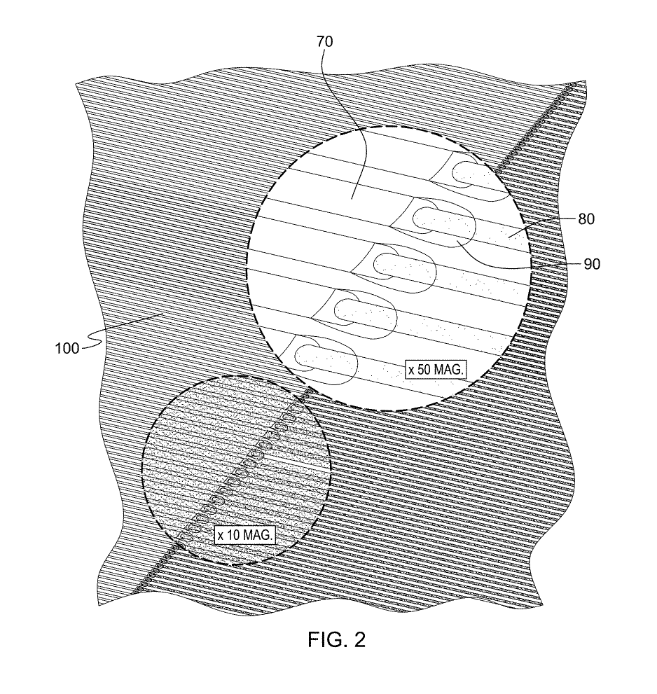

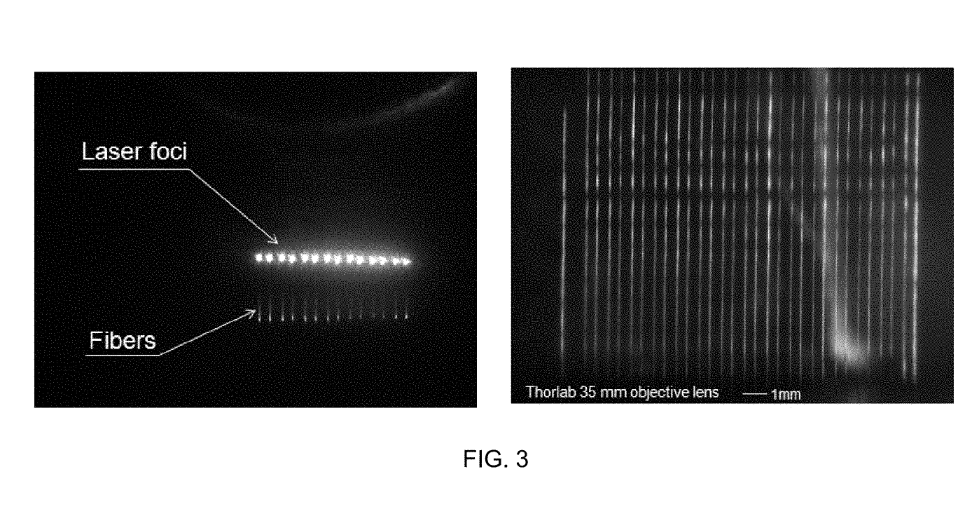

Also in accordance with that Application, a large array of independently controlled lasers can be provided, growing an equally large array of fibers 80 in parallel, as illustrated in FIG. 2, showing how fiber LCVD can be massively parallelized from a filament lattice 100 by multiplication of the laser beams 80 inducing a plasma 90 around the tip of each fiber 70. Using a CtP (e.g., QWI) laser array for LCVD is a scientific first, and so was the use of a shallow depth of focus. It provides very beneficial results. Sample carbon fibers, such as those shown in FIG. 3, were grown in parallel. FIG. 3 shows parallel LCVD growth of carbon fibers—Left: Fibers during growth and Right: Resulting free standing fibers 10-12 μm in diameter and about 5 mm long.

FIG. 4 depicts an exemplary embodiment of a plurality of rebarred fibers that may be formed using “digital spinneret” (DS) technology. This technology may also be referred to as fiber laser printing. The DS technology induces the growth of parallel monofilaments by massive parallelization of laser-induced chemical vapor deposition (LCVD). As illustrated in FIG. 4, the filament section 401 produced at a highest level of laser power, has the largest thickness. As laser power decreases smoothly over the section of filament 402, ending with section 403. As the laser power increases back up, so does filament thickness, until it maxes out at section 404. As one example, a SiCf ribbon may be produced by the method shown in FIG. 4. The resulting filaments may be β-SiC 3C with grain size distribution varying from the fiber center outward. Grains at the edge of the fiber are equiaxed. The anisotropy of the laser printing process manifests itself at the fiber's center where grains are elongated along the fiber's axis, and present an aspect ratio of 2-3 or more, with a radial size of about 25 nm or more. The grain distribution may provide additional toughness.

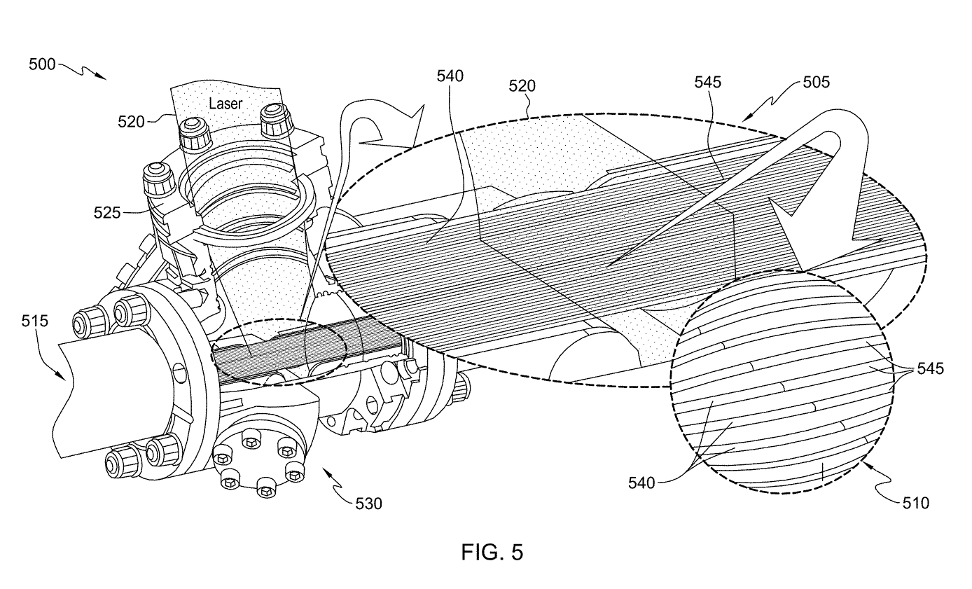

As noted, the embodiments of the processes disclosed herein may not only be applied to one fiber, but may be applied to multiple fibers arrayed together in a ribbon or tow-like structure, so that each layer of a multilayer fuel region for one fiber is also formed over the other multiple fibers, as shown in FIG. 5. Each step of layer formation may be carried out in a separate deposition tool, an example of which is depicted in FIG. 5, and the multiple fibers may be conveyed from one deposition tool to the next for the next layer to be deposited. As well, the deposition tool or tools may be controlled to automatically stop and start deposition of layers over the multiple fibers, thus allowing for a plurality of discrete multilayer fuel regions to be formed along the lengths of the multiple fibers while also automatically forming non-fuel regions of the fiber that separate the plurality of discrete multilayer fuel regions.

FIG. 5 depicts one example of a deposition tool 500 that may be used to form a layer of a multilayer region of at least one fiber, or respective layers of respective multilayer regions for a plurality of fibers. Deposition tool 500 may, for example, be a laser chemical vapor deposition (LCVD) tool. Deposition tool 500 may convey multiple fibers 530 through a conveyer inlet 515 into a deposition chamber 530. Deposition chamber may contain one or more precursor gases that may facilitate forming a layer of a multilayer region. A laser 520 may be provided, through a focusing lens or window 525, to be incident on multiple fibers 540 as the multiple fibers 540 are conveyed through the deposition chamber. As the laser 520 interacts with the multiple fibers 540 and precursor gases, the desired layer of a multilayer region may be deposited over portions of the multiple fibers 545. In one example, the laser may be started and stopped at defined intervals as the multiple fibers pass through the deposition tool 500, thus controlling formation of multilayer regions over portions of the multiple fibers 545 and leaving other portions unprocessed. The processed multiple fibers 545 may then be conveyed out of the deposition tool 500. The multiple fibers 545 may then be conveyed to another deposition tool, in which another layer of the discrete multilayer regions will be formed, or may be finished and conveyed out of the tool entirely. The resulting multiple fibers may then be further arranged in a structure, such as structure 500, to be wrapped around an inner rod structure. For clarity, FIG. 5 includes close-up views 510 and 515 of the multiple fibers 540, 545 as the multiple fibers undergo LCVD processing to deposit a layer of the multilayer regions.

By way of example, FIG. 6 depicts one embodiment of a nanoporous carbon layer, in accordance with one or more aspects of the present invention. As exemplified in FIG. 6, the material of the second inner layer region 602 may be, in one example, nanoporous carbon deposited upon a scaffold filament, such as a scaffold SiC fiber 601.

In an embodiment of the present invention depicted in FIG. 7, a method of making a nanofiber-coated fiber 700 is provided, which includes providing a base fiber 710, depositing a nanofreckle 720 on base fiber 710, and growing a nanofiber 730 at nanofreckle 720. As the figure illustrates, nanofiber 730 grows from nanofreckle 720 in three ways, singly or in combination: with nanofreckle 720 coupled directly to base fiber 710; with nanofreckle 720 somewhere along nanofiber 730; or, with nanofreckle 720 at the end of nanofiber 730 distal from base fiber 710.

In more detailed embodiments, base fiber 710 may comprise an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. As used herein, an “ordinarily solid material” means a material that is solid at a temperature of 20 degrees Celsius and a pressure of 1 atmosphere.

In another more detailed embodiment, base fiber 710 has a substantially non-uniform diameter. The non-uniformity of the diameter aids in coupling the fiber to the surrounding material matrix.

In more detailed embodiments, nanofreckle 720 may comprise a material selected from a group consisting of iron, cobalt, nickel, yttrium, zirconium, niobium, molybdenum, hafnium, tantalum, tungsten, rhenium, osmium, cerium, thorium, uranium, plutonium, and combinations thereof.

In more detailed embodiments, the act of depositing nanofreckle 720 on base fiber 710 may comprise or use one of the following methods: sputtering, chemical vapor deposition (CVD), or physical vapor deposition (PVD). Sputtering, CVD, and PVD are methods well known in the art.

In an even more detailed embodiment, depositing nanofreckle 720 on base fiber 710 may use laser-assisted CVD (LCVD). LCVD is a method well known in the art.

In another more detailed embodiment, the act of growing nanofiber 730 at nanofreckle 720 may comprise providing a precursor-laden environment 740 and triggering growth of nanofiber 730. In some embodiments, precursor-laden environment 740 may comprise a gas, liquid, critical fluid, supercritical fluid, or combinations thereof.

In another more detailed embodiment, precursor-laden environment 740 may comprise a hydrocarbon compound. In such embodiments, nanofiber 730 grows as a carbon nanotube.

In yet another more detailed embodiment, triggering growth of nanofiber 730 is accomplished using laser heating.

Some embodiments of the present invention may further comprise nanocombing nanofiber 730. As used herein “nanocombing” refers to any process by which a portion of nanofiber 730 distal from base fiber 710 is rendered substantially parallel to base fiber 710. Examples of nanocombing nanofiber 730 include, without limitation, drawing nanofiber-coated fiber 700 between parallel plates, through fixed holes, or through adjustable irises.

In another aspect of the present invention, nanofiber-coated fiber 700 may be an article of manufacture produced by any of the aforesaid method embodiments.

While only certain features of the invention have been illustrated and described herein, many modifications and changes will occur to those skilled in the art. It is, therefore, to be understood that the appended claims are intended to cover all such modifications and changes as fall within the true spirit of the invention.

Those skilled in the art will note from the above description that provided herein are methods of making a nanofiber-coated fiber. For instance, the method may include: providing a base fiber, the depositing a nanofreckle on the base fiber, and growing a nanofiber on the nanofreckle. In one or more implementations, the base fiber may include a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, in one or more embodiments, the base fiber may have a substantially non-uniform diameter. That is, the diameter of the base fiber may be selectively varied, as desired. In one or more embodiments, the nanofreckle may include a material selected from a group consisting of iron, cobalt, nickel, yttrium, zirconium, niobium, molybdenum, hafnium, tantalum, tungsten, rhenium, osmium, cerium, thorium, uranium, plutonium, and combinations thereof.

In one or more embodiments, the depositing of a nanofreckle on the base fiber may include one of sputtering, depositing by chemical vapor deposition or depositing by physical vapor deposition, the nanofreckle on the base fiber. In one or more embodiments, depositing a nanofreckle on the base fiber may include using laser-assisted chemical vapor deposition. Growing a nanofiber at the nanofreckle may include providing a precursor-latent environment, and triggering growth of the nanofiber. For instance, the precursor-latent environment may include a material selected from a group consisting of gasses, liquids, critical fluids, super-critical fluids, and combinations thereof. In one or more embodiments, the precursor-latent environment may include a hydrocarbon compound. In one or more implementations, triggering growth of the nanofiber may include laser heating. Further, the method of making a nanofiber-coated fiber may include nanocombing the nanofiber. In addition, in one or more embodiments, the method may further include chemically converting the nanofiber to a carbide nanofiber or an oxide nanofiber by reaction with a reagent gas.

In one or more embodiments, methods of making a nanofiber-coated fiber are disclosed herein which include: providing a base fiber, depositing a nanofreckle on the base fiber; providing a precursor-latent environment comprising a gaseous hydrocarbon compound; and laser-heating the nanofreckle to trigger growth of a nanofiber. In one or more embodiments, the nanofiber may include a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, in one or more embodiments, the base fiber may have a substantially non-uniform diameter. The non-uniform diameter may be selectively varied, as described herein. In one or more embodiments, the nanofreckle may comprise a material selected from a group consisting of iron, cobalt, nickel, yttrium, zirconium, niobium, molybdenum, hafnium, tantalum, tungsten, rhenium, osmium, cerium, thorium, uranium, plutonium, and combinations thereof.

In addition, in connection with this making a nanofiber-coated fiber, the depositing of the nanofreckle on the base fiber may include a method selected from a group consisting of sputtering, chemical vapor deposition, and physical vapor deposition of the nanofreckle. Further, the depositing of the nanofreckle on the base fiber may include laser-assisted chemical vapor deposition. In addition, the method may include nanocombing the nanofiber.

Nanofiber-coated fibers produced by a process such as summarized above are also described herein. For instance, a fiber structure is disclosed which includes: a base fiber; at least one nanofreckle deposited on the base fiber; and a nanofiber grown at a nanofreckle of the at least one nanofreckle. In one or more embodiments, the base structure may have a non-uniform diameter, as described herein. Also, in one or more implementations, the method may further include chemically converting the nanofiber to a carbide nanofiber or an oxide nanofiber by laser-induced chemical reaction with a reagent gas.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method of making a nanofiber-coated fiber, the method comprising:
providing a base fiber;
depositing a nanofreckle on the base fiber; and
growing a nanofiber at the nanofreckle.

2. The method of claim 1, wherein the base fiber comprises a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

3. The method of claim 1, wherein the base fiber has a substantially non-uniform diameter.

4. The method of claim 1, wherein the nanofreckle comprises a material selected from a group consisting of iron, cobalt, nickel, yttrium, zirconium, niobium, molybdenum, hafnium, tantalum, tungsten, rhenium, osmium, cerium, thorium, uranium, plutonium, and combinations thereof.

5. The method of claim 1, wherein the depositing a nanofreckle on the base fiber comprises a method selected from a group consisting of sputtering, chemical vapor deposition, and physical vapor deposition of the nanofreckle.

6. The method of claim 1, wherein the depositing a nanofreckle on the base fiber comprises using laser-assisted chemical vapor deposition.

7. The method of claim 1, wherein the growing a nanofiber at the nanofreckle comprises:
providing a precursor-laden environment; and
triggering growth of the nanofiber.

8. The method of claim 7, wherein the precursor-laden environment comprises a material selected from a group consisting of gases, liquids, critical fluids, supercritical fluids, and combinations thereof.

9. The method of claim 7, wherein the precursor-laden environment comprises a hydrocarbon compound.

10. The method of claim 7, wherein the triggering growth of the nanofiber comprises laser heating.

11. The method of claim 1, further comprising nanocombing the nanofiber.

12. The method of claim 1, further comprising chemically converting the nanofiber to a carbide nanofiber or an oxide nanofiber by reaction with a reagent gas.

13. A method of making a nanofiber-coated fiber, the method comprising:
providing a base fiber;
depositing a nanofreckle on the base fiber;
providing a precursor-laden environment comprising a gaseous hydrocarbon compound; and
laser heating the nanofreckle to trigger growth of a nanofiber.

14. The method of claim 13, wherein the base fiber comprises a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

15. The method of claim 13, wherein the base fiber has a substantially non-uniform diameter.

16. The method of claim 13, wherein the nanofreckle comprises a material selected from a group consisting of iron, cobalt, nickel, yttrium, zirconium, niobium, molybdenum, hafnium, tantalum, tungsten, rhenium, osmium, cerium, thorium, uranium, plutonium, and combinations thereof.

17. The method of claim 13, wherein the depositing a nanofreckle on the base fiber comprises a method selected from a group consisting of sputtering, chemical vapor deposition, and physical vapor deposition of the nanofreckle.

18. The method of claim 13, wherein the depositing a nanofreckle on the base fiber comprises using laser-assisted chemical vapor deposition.

19. The method of claim 13, further comprising nanocombing the nanofiber.

20. The method of claim 13, further comprising chemically converting the nanofiber to a carbide nanofiber oxide nanofiber by laser-induced chemical reaction with a reagent gas.

21. A fiber structure comprising:
a base fiber;
at least one nanofreckle deposited on the base fiber; and
a nanofiber grown at a nanofreckle of the at least one nanofreckle.

22. The fiber structure of claim 21, wherein the base structure has a non-uniform diameter.
